(19) United States
(12) Patent Application Publication
(10) Pub. No.: US 2017/0229672 A1
(43) Pub. Date: Aug. 10, 2017

(54) ORGANIC LIGHT EMITTING DEVICES AND METHODS OF MAKING THEM

(71) Applicants: Cambridge Display Technology Limited, Godmanchester (GB); Novaled GmbH, Dresden (DE)

(72) Inventors: Ulrich DENKER, Dresden (DE); Jan BIRNSTOCK, Dresden (DE); Graham ANDERSON, Cambridge (GB); Elliott SPAIN, Cambridge (GB); Oscar FERNANDEZ, Veldhoven (NL); Ilaria GRIZZI, Ely (GB)

(21) Appl. No.: 15/501,604

(22) PCT Filed: Jul. 30, 2015
(86) PCT No.: PCT/GB2015/052197

§ 371 Date: Feb. 3, 2017

(30) Foreign Application Priority Data
Aug. 4, 2014 (GB) 1413774.9

(51) Int. Cl. H01L 51/50; H01L 51/00

(52) U.S. Cl. CPC H01L 51/5076; H01L 51/0008; H01L 51/5056; H01L 51/5012; H01L 51/5004; H01L 2251/558; H01L 2251/552; H01L 51/0084; H01L 51/0072; H01L 51/0039; H01L 51/0043

(57) ABSTRACT

An organic light emitting device comprises a light emitting layer comprising a light emitting polymer; and an electron transporting layer on the light emitting layer and comprising an electron transporting material and an n-donor material. The electron transporting layer comprises at least 20 percent by weight of the n-donor material. By using an electron transporting layer comprising at least 20 percent by weight of the n-donor material it is possible to realise devices with an electron transporting layer having a thickness of less than 20 nm.

### FIELD OF THE INVENTION

The present invention relates to organic light-emitting devices and methods of making them. More specifically, it relates to organic light-emitting devices comprising polymer light-emitting layers and non-polymeric (also known as “small-molecule”) electron-transporting layers. Such devices are sometimes known as “hybrid devices”.

### BACKGROUND

Electronic devices comprising active organic materials are attracting increasing attention for use in devices such as organic light-emitting diodes (OLEDs), organic photo responsive devices (in particular organic photovoltaic devices and organic photosensors), organic transistors and memory devices. Devices comprising organic materials offer benefits such as low weight, low power consumption and flexibility, and they can be employed in the manufacturing of displays or lighting appliances. Use of soluble organic materials, either polymers or small-molecules, allows use of solution processing in device layer manufacture, for example inkjet printing, spin-coating, dip-coating, slot dye printing, nozzle printing, roll-to-roll printing, gravure printing and flexographic printing. Moreover, use of non-soluble small-molecules enables the manufacturing of device layers by vacuum deposition. Examples of vacuum deposition methods are vacuum sublimation and the co-evaporation (or simultaneous evaporation) of a plurality of different small-molecule materials.

An OLED may comprise a substrate carrying an anode, a cathode, one or more organic light-emitting layers, and one or more charge injecting and/or charge transporting layers between the anode and cathode.

Holes are injected into the device by the anode and electrons are injected by the cathode during operation of the device. Holes in the highest occupied molecular orbital (HOMO) and electrons in the lowest unoccupied molecular orbital (LUMO) of a light-emitting material combine to form an exciton that releases its energy as light upon recombination.

A light-emitting layer consists of or includes light-emitting materials which may include small-molecule, polymeric and dendrimeric materials. Suitable light-emitting polymers include poly(arylene vinylenes), such as poly(p-phenylene vinylenes) as disclosed in WO 90/13148, and polyarylenes, such as polyfluorenes. In U.S. Pat. No. 4,539,507 the light-emitting material is (8-hydroxyquinoline) aluminium (“Alq3”, ET3). WO 99/21935 discloses dendrimer light-emitting materials.

A light-emitting layer may alternatively consist of or include a semiconducting host material and a light-emitting dopant wherein energy is transferred from the host material to the light-emitting dopant. For example, J. Appl. Phys. 65, 3610, 1989 discloses a host material doped with a fluorescent light-emitting dopant (that is, a light-emitting material in which light is emitted via decay of a singlet exciton) and Appl. Phys. Lett., 2000, 77, 904 discloses a host material doped with a phosphorescent light emitting dopant (that is, a light-emitting material in which light is emitted via decay of a triplet exciton).

A charge transporting layer consists of or includes materials suitable for transporting holes and/or electrons, which may include small-molecule, polymeric and dendrimeric materials. Suitable electron-transporting polymers include triazines and pyrimidines, such as those disclosed in U.S. Pat. No. 8,003,227. Suitable hole-transporting polymers include triarylamines, such as those disclosed in the Applicant's earlier applications WO 02/066537 and WO 2004/084260.

In a typical OLED structure, the electron-transporting layer comprising host-dopant small-molecule materials may be vapour deposited directly onto a light-emitting layer comprising a polymer, and then capped with a thermally evaporated metal layer. The metal layer typically forms a cathode metal contact of the device.

### SUMMARY OF THE INVENTION

According to a first aspect of the present invention, an organic light emitting device comprises a light emitting layer comprising a light emitting polymer; and an electron transporting layer on the light emitting layer and comprising an electron transporting material and an n-donor material. The electron transporting layer comprises at least 20 percent by weight of the n-donor material.

By doping the electron transporting layer with 20 percent or more by weight of the n-donor material, it has been found that the thickness of the electron transporting layer can be reduced to less than 20 nm while maintaining desirable electron injection properties of the OLED device. Reducing the thickness of the electron transporting layer is beneficial as it allows the optical cavity properties for the OLED device to be optimised and therefore colour stability of the device to be optimised.

In an embodiment, the electron transporting layer has a thickness of less than 20 nm.

In an embodiment, the electron transporting layer has a thickness of less than 10 nm.

In an embodiment, the electron transporting layer has a thickness of less than 5 nm.

The electron transport layer of the invention preferably has a thickness of greater than 1 nm.

In an embodiment, the electron transporting layer comprises at least 40 percent by weight of the n-donor material.

In an embodiment, the electron transporting layer comprises at least 50 percent by weight of the n-donor material.

The electron transport layer of the invention preferably comprises less than or equal to 80 percent by weight of the n-donor material.

In an embodiment, substantially all molecules of the n-donor material are complexed with molecules of the electron transporting material.

According to a second aspect of the present invention an organic light emitting device comprises a light emitting layer comprising a light emitting polymer; and an electron transporting layer. The electron transporting layer comprises an electron transporting material and an n-donor material, at least 20 percent of the molecules of the electron transporting material are complexed with molecules of the n-donor material.

The doping properties leading to a reduction in thickness of the electron transporting layer can also be defined in terms of the percentage of molecules of the electron transporting material that are complexed with molecules of the n-donor material.

In an embodiment, at least 50 percent of the molecules of the electron transporting material are complexed with molecules of the n-donor material.

In an embodiment, at least 80 percent of the molecules of the electron transporting material are complexed with molecules of the n-donor material.

In an embodiment, the ratio of molecules of the electron transporting material to molecules of the n-donor material is 1:1.

In an embodiment, the device further comprises a metal cathode disposed on the electron transporting layer.

In an embodiment, the electron transporting layer comprising the n-donor material is formed directly on the light emitting layer.

By doping the electron transporting layer with 20 percent or more by weight of the n-donor material, it has been found that the electron transporting layer comprising the n-donor material can be formed directly on the light emitting layer while maintaining desirable electron injection properties of the OLED device. Reducing the number of layers in the device is beneficial as it allows faster, easier and cheaper manufacturing processes.

In an embodiment, the n-donor material is a molecular dopant material.

In an embodiment, the n-donor material is a molecular redox dopant material.

In an embodiment, the n-donor material is a substantially organic redox dopant material.

In an embodiment, the n-donor material is a transition metal complex, preferably a paddle wheel complex.

In an embodiment, the n-donor material is tetrakis (1,3,4,6,7,8-hexahydro-2H-pyrimido [1,2-a] pyrimidinato) ditungsten (II) (ND1).

In an embodiment, the n-donor material is free of Lithium salt or Lithium organic metal complex.

By doping the electron transporting layer with at least 20 percent by weight of an n-donor material which is a molecular dopant material, preferably a molecular redox dopant material, and which is free of Lithium salt or Lithium organic metal complex, electron injection properties can be achieved which are suitable for commercial products.

In an embodiment, the electron transporting material comprises a phenanthroline compound or a metal quinolate.

In an embodiment, the electron transporting material comprises a phenanthroline compound.

In an embodiment, the electron transporting material comprises a metal quinolate.

In an embodiment, the electron transporting material comprises ET1 or ET2 which are illustrated below:

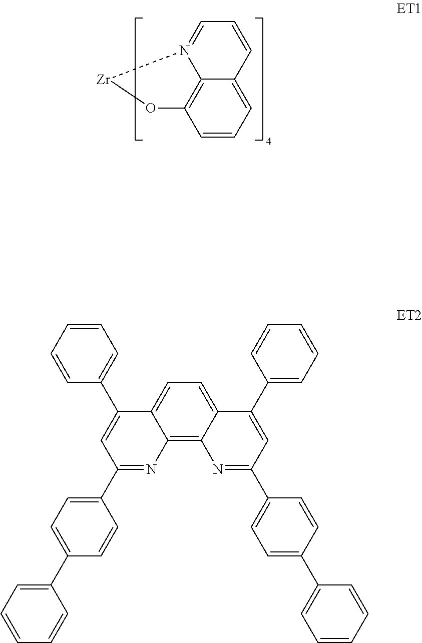

In an embodiment, ET1 is used for the electron transporting material and a doping ratio of at least 30% by weight of ND1 is used and the electron transporting layer is less than 10 nm thick.

In an embodiment ET1 is used for the electron transporting material and a doping ratio of 30% to 50% by weight of ND1 is used and the electron transporting layer is less than 10 nm thick.

In an embodiment ET2 is used for the electron transporting material and a doping ratio of at least 70% by weight of ND1 is used and the electron transporting layer is less than 10 nm thick.

In an embodiment ET2 is used for the electron transporting material and a doping ratio of 70% to 90% by weight of ND1 is used and the electron transporting layer is less than 10 nm thick.

According to a third aspect of the present invention, a process for the preparation of an organic light emitting device comprises depositing a solution of a light emitting polymer over an anode layer; and vapour depositing an electron transporting material and an n-donor material to form an electron transporting layer over the light emitting polymer.

The electron transporting layer comprises at least 20 percent by weight of an n-donor material.

In an embodiment, the electron transporting layer has a thickness of less than 20 nm.

In an embodiment, the electron transporting layer has a thickness of less than 10 nm.

In an embodiment, the electron transporting layer has a thickness of less than 5 nm.

In an embodiment, the electron transporting layer comprises at least 40 percent by weight of the n-donor material.

In an embodiment, the electron transporting layer comprises at least 50 percent by weight of the n-donor material.

In an embodiment, depositing a solution of a light emitting polymer is conducted by spin-coating, inkjet-printing, slot die coating, screen printing or dip-coating.

### BRIEF DESCRIPTION OF THE DRAWINGS

In the following, embodiments of the invention will be described, by way of example, with reference to the drawings in which:

FIG. 1 shows an OLED regarded as a comparative example;

FIG. 2 shows an OLED according to an embodiment of the present invention;

FIG. 3 is a graph showing the effect of varying the thickness of the electron transporting layer in embodiments of the present invention;

FIG. 4 shows current density against applied bias voltage different thickness electron transporting layers in embodiments of the present invention;

FIG. 5 shows luminance against time for different doping levels in an OLED device according to an embodiment of the present invention;

FIG. 6 shows drive voltage increase over the T-50 lifetime for different doping levels in an OLED device according to an embodiment of the present invention; and

FIG. 7 shows a comparison of dV for different hosts in embodiments of the present invention.

### DETAILED DESCRIPTION

Anode

The anode typically comprises a transparent conducting material such as an inorganic oxide or a conducting polymer.

Cathode

The cathode typically comprises a conductive metal such as Al or Cu or Ag or a highly conductive alloy, with an optional alkali metal halide or oxide or an alkaline earth halide or oxide layer in electrical contact with the electron transport layer.

Light-Emitting Layer

The light-emitting material(s) of the light-emitting layer may be selected from polymeric and non-polymeric light-emitting materials. Exemplary light-emitting polymers are conjugated polymers, for example polyphenylenes and polyfluorenes examples of which are described in Bernius, M. T., Inbasekaran, M., O'Brien, J. and Wu, W., Progress with Light-Emitting Polymers. Adv. Mater., 12: 1737-1750, 2000, the contents of which are incorporated herein by reference.

A conjugated light-emitting polymer may comprise one or more amine repeat units of formula (I):

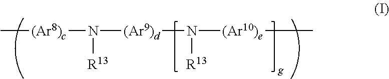

wherein Ar⁸, Ar⁹ and Ar¹⁰ in each occurrence are independently selected from substituted or unsubstituted aryl or heteroaryl, g is 0, 1 or 2, preferably 0 or 1, R¹³ independently in each occurrence is H or a substituent, preferably a substituent, and c, d and e are each independently 1, 2 or 3.

R¹³, which may be the same or different in each occurrence when g is 1 or 2, is preferably selected from the group consisting of alkyl, for example C₁₋₂₀ alkyl, Ar¹¹ and a branched or linear chain of Ar¹¹ groups wherein Ar¹¹ in each occurrence is independently substituted or unsubstituted aryl or heteroaryl.

Any two aromatic or heteroaromatic groups selected from Ar⁸, Ar⁹, and, if present, Ar¹⁰ and Ar¹¹ that are directly bound to the same N atom may be linked by a direct bond or a divalent linking atom or group. Preferred divalent linking atoms and groups include O, S; substituted N; and substituted C.

Ar⁸ and Ar¹⁰ are preferably C₆₋₂₀ aryl, more preferably phenyl, that may be unsubstituted or substituted with one or more substituents.

In the case where g=0, Ar⁹ is preferably C₆₋₂₀ aryl, more preferably phenyl, that may be unsubstituted or substituted with one or more substituents.

In the case where g=1, Ar⁹ is preferably C₆₋₂₀ aryl, more preferably phenyl or a polycyclic aromatic group, for example naphthalene, perylene, anthracene or fluorene, that may be unsubstituted or substituted with one or more substituents.

R¹³ is preferably Ar¹¹ or a branched or linear chain of Ar¹¹ groups. Ar¹¹ in each occurrence is preferably phenyl that may be unsubstituted or substituted with one or more substituents.

Exemplary groups R¹³ include the following, each of which may be unsubstituted or substituted with one or more substituents, and wherein * represents a point of attachment to N:

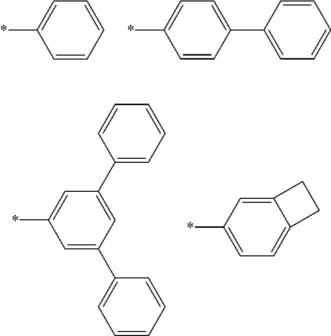

c, d and e are preferably each 1.

Ar⁸, Ar⁹, and, if present, Ar¹⁰ and Ar¹¹ are each independently unsubstituted or substituted with one or more, optionally 1, 2, 3 or 4, substituents. Exemplary substituents may be selected from substituted or unsubstituted alkyl, optionally C₁₋₂₀ alkyl, wherein one or more non-adjacent C atoms may be replaced with optionally substituted aryl or heteroaryl (preferably phenyl), O, S, C═O or —COO— and one or more H atoms may be replaced with F.

Preferred substituents of Ar⁸, Ar⁹, and, if present, Ar¹⁰ and Ar¹¹ are C₁₋₄₀ hydrocarbyl, preferably C₁₋₂₀ alkyl.

Preferred repeat units of formula (I) include unsubstituted or substituted units of formulae (I-1), (I-2) and (I-3):

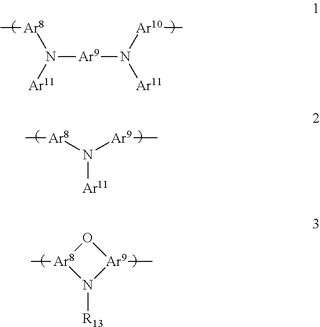

A light-emitting polymer comprising repeat units of formula (I) may further comprise one or more arylene repeat units. Exemplary arylene repeat units are phenylene, fluorene, indenofluorene and phenanthrene repeat units, each of which may be unsubstituted or substituted with one or more substituents, optionally one or more C₁₋₄₀ hydrocarbyl groups. Exemplary hydrocarbyl groups include C₁₋₂₀ alkyl; unsubstituted phenyl; and phenyl substituted with one or more C₁₋₂₀ alkyl groups.

Polymers as described herein including, without limitation, inert polymers and light-emitting polymers, may have a polystyrene-equivalent number-average molecular weight (Mn) measured by gel permeation chromatography in the range of about 1×10³ to 1×10⁸, and preferably 1×10³ to 5×10⁶. The polystyrene-equivalent weight-average molecular weight (Mw) of the polymers described herein may be 1×10³ to 1×10⁸, and preferably 1×10⁴ to 1×10⁷.

Polymers as described herein including, without limitation, inert polymers and light-emitting polymers, are preferably amorphous.

The light emitting layer may comprise a fluorescent or phosphorescent dopant provided in light-emitting layer 103 with a host material. Exemplary phosphorescent dopants are row 2 or row 3 transition metal complexes, for example complexes of ruthenium, rhodium, palladium, rhenium, osmium, iridium, platinum or gold. Iridium is particularly preferred.

Hole-Transporting Layer

A hole transporting layer may be provided between the anode and the light-emitting layer or layers of an OLED.

If present, a hole transporting layer located between the anode and the light-emitting layer(s) preferably has a material having a HOMO level of less than or equal to 5.5 eV, more preferably around 4.8-5.5 eV or 4.9-5.3 eV as measured by cyclic voltammetry. The HOMO level of the material in the hole transport layer may be selected so as to be within 0.2 eV, optionally within 0.1 eV of the light-emitting material of the light-emitting layer.

A hole-transporting layer may contain polymeric or non-polymeric hole-transporting materials. Exemplary hole-transporting polymers are homopolymers and copolymers comprising repeat units of formula (I) as described above.

A hole-transporting layer may be crosslinked, particularly if a layer overlying that charge-transporting or charge-blocking layer is deposited from a solution. The crosslinkable group used for this crosslinking may be a crosslinkable group comprising a reactive double bond such and a vinyl or acrylate group, or a benzocyclobutane group. The crosslinkable group may be provided as a substituent of, or may be mixed with, a hole-transporting material used to form the hole-transporting layer.

A hole-transporting layer adjacent to a light-emitting layer containing a phosphorescent light-emitting material preferably contains a charge-transporting material having a lowest triplet excited state (T₁) excited state that is no more than 0.1 eV lower than, preferably the same as or higher than, the T₁ excited state energy level of the phosphorescent light-emitting material(s) in order to avoid quenching of triplet excitons.

A hole-transporting layer as described herein may be non-emissive, or may contain a light-emitting material such that the layer is a charge transporting light-emitting layer. If the hole-transporting material a polymer then a light-emitting dopant may be provided as a side-group of the polymer, a repeat unit in a backbone of the polymer, or an end group of the polymer. Optionally, a hole-transporting polymer as described herein comprises a phosphorescent polymer in a side-group of the polymer, in a repeat unit in a backbone of the polymer, or as an end group of the polymer.

The polystyrene-equivalent number-average molecular weight (Mn) measured by gel permeation chromatography of the polymers described herein may be in the range of about 1×10³ to 1×10⁸, and preferably 1×10⁴ to 5×10⁶. The polystyrene-equivalent weight-average molecular weight (Mw) of the polymers described herein may be 1×10³ to 1×10⁸, and preferably 1×10⁴ to 1×10⁷.

Polymers as described herein are suitably amorphous.

Electron Transport Layer (ETL)

Advantageously, an electron-transporting layer comprises a semiconducting host material and a semiconducting dopant material. Suitable host-dopant material systems include small-molecule materials. The host and the dopant materials can be deposited simultaneously by vapour deposition to form an electron-transporting layer comprising a mixture or blend of the host and dopant materials.

### EXAMPLES

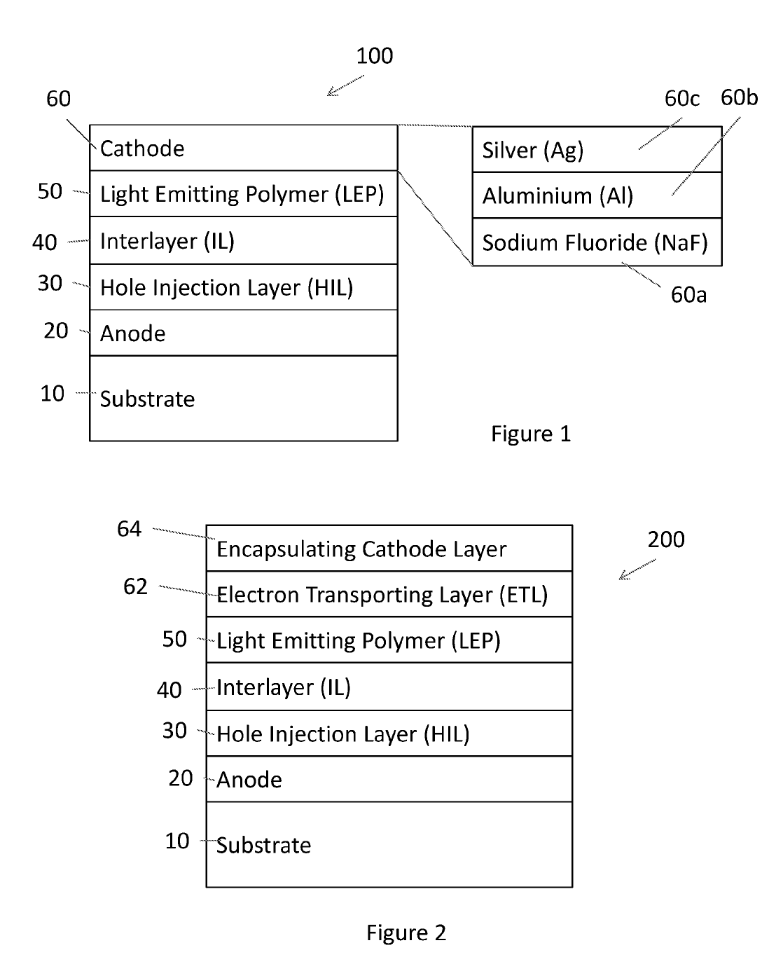

FIG. 1, which is not drawn to any scale, illustrates schematically an OLED 100 regarded as a Comparative Example for OLEDs in accordance with embodiments of the present invention. The OLED 100 structure is deposited on a substrate 10, typically made of glass, and comprises several layers provided in the following sequence on the substrate: an anode electrode 20, a hole injection layer (HIL) 30, an interlayer (IL) 40, a light-emitting polymer (LEP) layer 50 and a cathode electrode 60.

The anode electrode 20, typically made of ITO (indium tin oxide), is 45 nm thick and is deposited by physical vapour deposition such as vacuum or thermal evaporation. The HIL 30 is 50 nm thick and is deposited by spin coating a solution of a hole-injecting material called Plexcore© OC AQ-1200 as available from Plextronics Inc. The IL 40 is 22 nm thick, and is deposited by spin coating a solution of the hole-transporting polymer P10. The polymer P10 comprises the monomers M11 to M14 in the following weight percentages: 50% M11, 30% M12, 12.5% M13 and 7.5% M14. The chemical structures of these monomers are shown below:

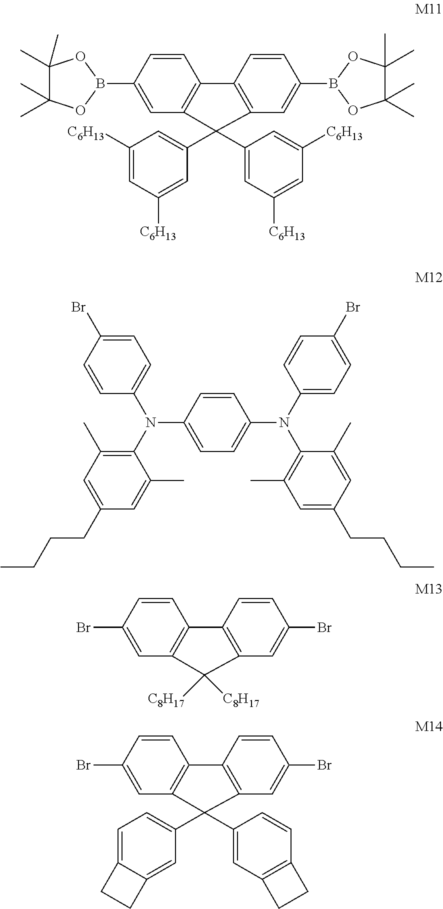

The LEP layer 50 is 60 nm thick and is deposited by spin coating a solution of the light-emitting polymer P20. The polymer P20 comprises the monomers M21 to M25 in the following weight percentages: 36% M21, 14% M22, 45% M23, 4% M24 and 1% M25. The chemical structures of these monomers are shown below:

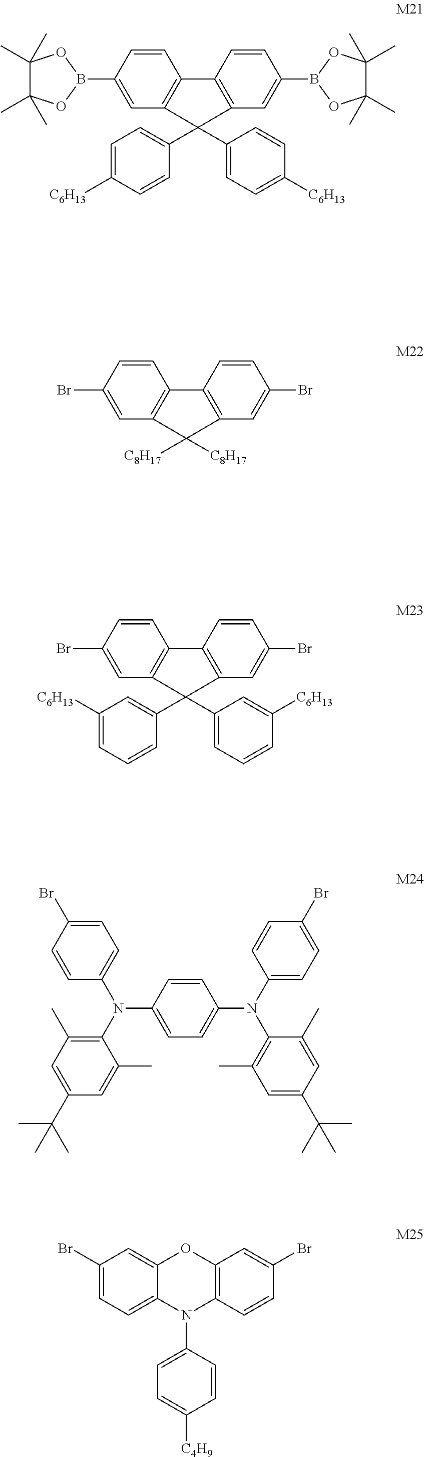

The polymers P10 and P20 were synthesized using the Suzuki polymerisation method, as it is well known in the art. Monomer M11 has been disclosed in WO2002/092723, M12 in WO2005/074329, M13 in WO2002/092724, M14 in WO2005/038747, M21 in WO2002/092724, M22 in U.S. Pat. No. 6,593,450, M23 in WO2009/066061, M24 in WO2010/013723, and M25 in WO2004/060970.

The cathode electrode 60 consists of three stacked layers of NaF 60a, Al 60b and Ag 60c, having a thickness of 4 nm, 100 nm and 100 nm respectively. The NaF is deposited by thermal evaporation on the LEP layer 50 and then encapsulated by the thermally evaporated bi-layer stack of Al and Ag.

In operation, holes injected from the anode electrode 20 and electrons injected from the cathode electrode 60 combine in the LEP layer 50 to form excitons which may decay radiatively to provide light upon recombination.

FIG. 2, which is not drawn to any scale, illustrates schematically embodiments of OLEDs 200 in accordance with the first aspect of the present invention. In FIG. 2 like reference numerals have been used for corresponding parts to FIG. 1. Instead of having three stacked cathode layers of NaF, Al and Ag on the LEP layer 50, the OLED 200 of the invention comprises a bi-layer having an electron-transporting layer (ETL) 62 and an Al encapsulating cathode layer 64. In a preferred embodiment, the ETL 62 is deposited directly on the LEP layer 50. Surprisingly, the authors have found that a buffer layer is not required between the LEP layer 50 and ETL 62 if the ETL 62 comprises at least 20 percent by weight of an n-donor material. Both layers are deposited by thermal evaporation. The Al encapsulating layer has a thickness of 200 nm. In the following description, the effect of varying the thickness and composition of the ETL 62 is discussed.

One advantage of the device shown in FIG. 2 over the device shown in FIG. 1 is that it allows the use of different hosts and dopants in the ETL to tailor injection properties to different LEP Lowest Unoccupied Molecular Orbital (LUMO) properties. In terms of deposition, the temperatures for ETL evaporation in the device shown in FIG. 2 are much lower (˜200 C) than for the NaF device shown in FIG. 1 (˜750 C). Thus the device shown in FIG. 2 provides ease of fabrication. Further, it is important that the substrate temperature does not increase much above ambient during deposition, so using NaF inherently requires the source to be far away from the substrate.

Further, the choice of cathode material in the device shown in FIG. 2 is less limited than for the device shown in FIG. 1. For example Au, Ag or ITO can be used with doped ETLs without an Al interlayer which is needed for NaF.

Compounds which are suitable for use as electron-transporting material are disclosed for example in Yasuhiko Shirota and Hiroshi Kageyama, Chem. Rev. 2007, 107, 953-1010 and incorporated by reference. In one example, the electron-transporting material may be a phenanthroline compound. Phenanthroline compounds which can be suitably used are disclosed in EP1786050 and incorporated by reference. In one example, the electron-transporting material may be a metal quinolate. Metal quinolates which can be suitably used are disclosed in JP 2001076879 and incorporated by reference.

Further examples of doped electron transport materials are: fullerene C60 doped with acridine orange base (AOB); perylene-3,4,9,10-tetracarboxylic-3,4,9,10-dianhydride (PTCDA) doped with leuco crystal violet; 2,9-di (phenanthren-9-yl)-4,7-diphenyl-1,10-phenanthroline doped with tetrakis (1,3,4,6,7,8-hexahydro-2H-pyrimido [1,2-a] pyrimidinato) ditungsten (II) (W2(hpp)4, (ND1); naphthalene tetracarboxylic acid di-anhydride (NTCDA) doped with 3,6-bis-(dimethyl amino)-acridine; NTCDA doped with bis(ethylene-dithio) tetrathiafulvalene (BEDT-TTF).

In the present example the ETL 62 comprises an electron-transporting material containing one of the small-molecule hosts such as ET1 and ET2. The chemical structures of ET1 and ET2 are illustrated below:

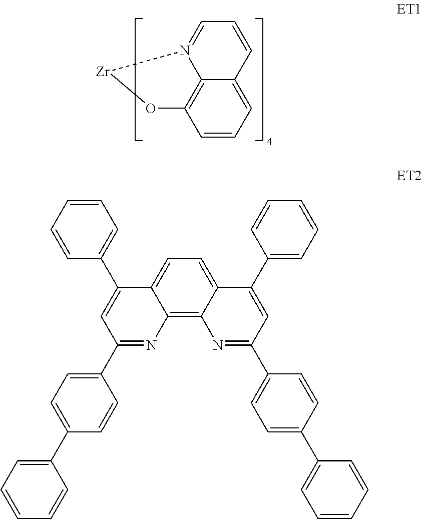

The ETL 62 comprises an n-donor material. The n-donor material is a compound which is capable of electrically doping a matrix compound via a redox process. One or more electrons are transferred from the n-donor material to the matrix compound in a charge transfer mechanism. To achieve efficient electron transfer, the HOMO level of the n-donor material has to be energetically above the LUMO level of the matrix compound. HOMO and LUMO levels can be measured, for example by cyclic voltammetry. Energy levels can be converted from tabulated ionization potentials (IP) and electron affinities (EA) by applying Koopman's theorem. IP and EA of commonly used compounds can be found in the literature, for example Shirota and Kageyama, Chem. Rev. 2007, 107, 953-10101.

In one example, the n-donor material may be a substantially organic redox dopant material. Suitable organic redox dopant materials are for example heterocyclic radical and diradical compounds disclosed in US2007252140A1 and incorporated by reference. Particularly suitable are biimidazole compounds. Other suitable organic n-donor materials are leuko bases disclosed in US2005040390A1 and incorporated by references. Particularly suitable is leuko crystal violet.

In one example, the n-donor material may be a transition metal complex. Particularly suitable are paddle wheel complexes disclosed in US2009212280A1 and incorporated by reference. Particularly preferred is tetrakis (1,3,4,6,7,8-hexahydro-2H-pyrimido [1,2-a] pyrimidinato) ditungsten (II) (ND1).

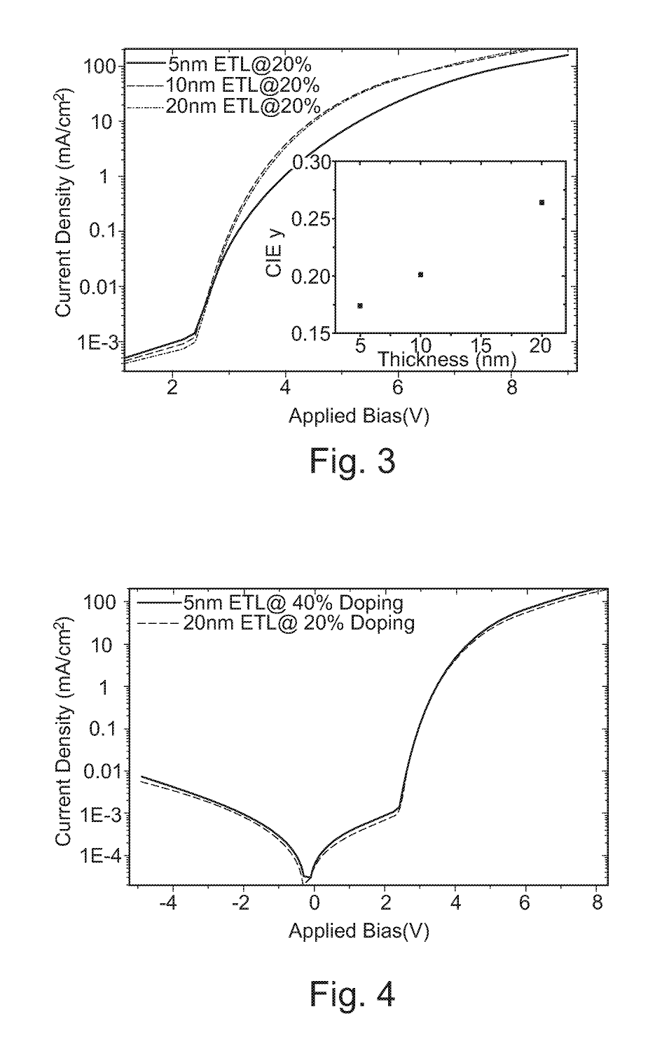

FIG. 3 is a graph showing the effect of varying the thickness of the ETL between 20 nm and 5 nm. In the device for which results are illustrated in FIG. 3, the ETL comprises ET1 doped with 20% by weight with ND1. FIG. 3 shows results for a 5 nm thick ETL, a 10 nm thick ETL and a 20 nm thick ETL. FIG. 3 shows current density against applied bias voltage for the different thickness and the inset graph illustrates the CIE y chrominance parameter for each of the thicknesses.

FIG. 3 shows the decreased electron injection resulting from thinning the ETL from 20 nm to 5 nm. The inset graph demonstrates that the CIE y colour parameter of the 20 nm ETL device is above that expected for a NaF device shown in FIG. 1. The NaF device shown in FIG. 1a has a CIE y value of 0.18. The reason for this variation is that the thickness of the ETL modifies the optical cavity properties of the device. The cavity thickness of the NaF device shown in FIG. 1a is 4 nm.

As shown in FIG. 3, the CIE y value for an ETL with a thickness of 5 nm is close to 0.18.

FIG. 4 shows current density against applied bias voltage for a 5 nm thick ETL comprising ET1 doped at 40% by weight with ND1, and an ETL with a thickness of 20 nm comprising ET1 doped at 20% by weight with ND1. As shown in FIG. 4, the current density characteristics of the two devices are similar. Thus by increasing the doping ratio to 40% by weight, the thickness of the ETL can be reduced to 5 nm without a great impact on the electron injection properties.

The table below shows the measured colour parameters for the devices described above in relation to FIG. 4.

| | CIE x | CIE y |
|---|---|---|
| 5 nm ETL @ 40% doping | 0.14 | 0.18 |
| 20 nm ETL @ 20% doping | 0.15 | 0.27 |

As shown in the table above, the reduction in the thickness of the ETL brings the CIE y colour value down to 0.18. This is a similar value to that of a NaF-based cathode device as shown in FIG. 1. Thus by increasing the doping concentration of the ETL it is possible to reduce the thickness of the ETL and therefore achieve similar colour properties to a NaF-based cathode device.

As the doping ratio of the ETL between the host and the dopant is increased more host is complexed with the dopant. However, once the dopant level is beyond a certain point there is not enough host for the dopant to complex with. This results in non-complexed dopant being present in the ETL. The dopant is very reactive on its own; therefore the presence of uncomplexed dopant in the ETL can be detrimental to the lifetime properties of an OLED device.

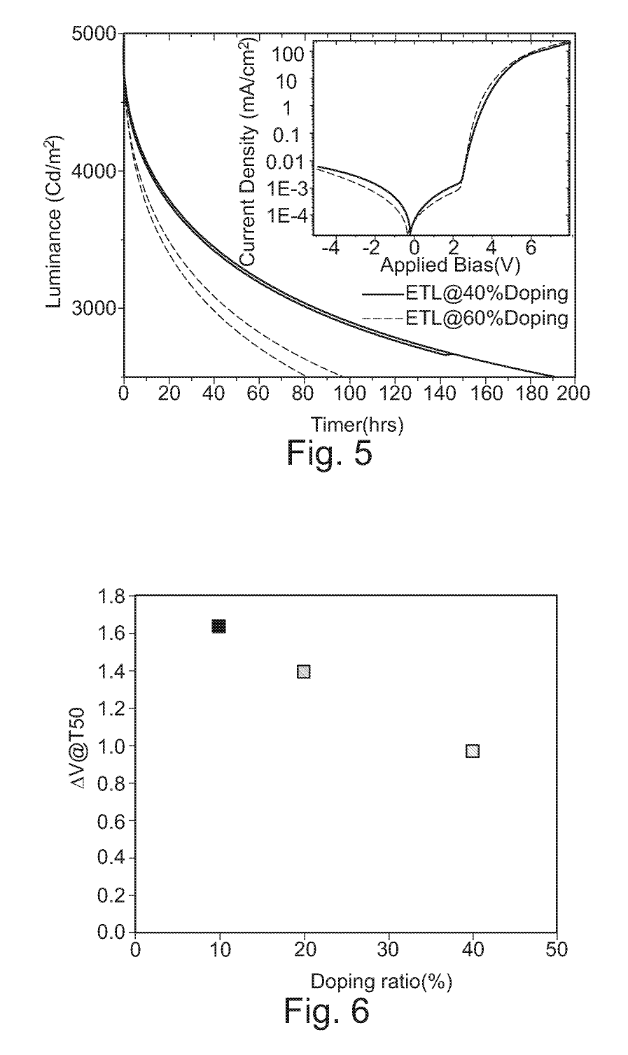

FIG. 5 shows luminance against time for different doping levels in an OLED device having an ETL with a thickness of 5 nm comprising ET1 doped with ND1. As shown in FIG. 5, increasing the doping from 40% to 60% by weight results in poor luminance properties. As discussed above, this is thought to be due to the presence of the un-complexed dopant in the ETL. The inset graph shows current density against applied voltage. This graph shows that the current voltage characteristics are largely unchanged even with different doping levels.

FIG. 6 shows the drive voltage (V_{d}) increase (ΔV) over the T-50 lifetime at constant current for different doping levels in an OLED device having an ETL with a thickness of 5 nm comprising ET1 doped with ND1. The V_{d} increase is a good metric of charge injection stability. As shown in FIG. 6, an increase in the doping level results in a decrease in the V_{d} increase. Thus, increased doping levels are also advantageous with regard to ΔV over the lifetime. By increasing the doping level from 10% to 40%, ΔV can be reduced from 1.7V to below 1V.

This process of varying the dopant ratio has been shown to transfer to other host systems. Adjustments must be made to account for the size of the host molecule.

In an embodiment, ET2 is used as a host. For ET2 compared to ET1 for example the maximum doping percentage before non-complexed dopant is present is 80% by weight compared to 50% by weight.

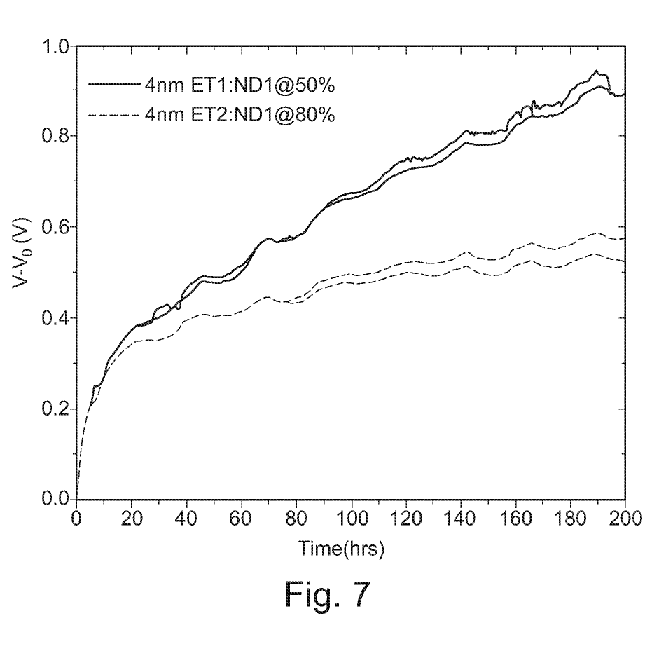

FIG. 7 shows a comparison of dV for hosts ET1 and ET2. As shown in FIG. 7, using ET2 instead of ET1 improves dV. One possible explanation for this is the higher doping level for ET2.

When ET1 is used for the electron transporting material a doping ratio of 30-50% by weight of ND1 is may be used. When ET2 is used for the electron transporting material a doping ratio of 70-90% by weight of ND1 is may be used. These doping percentages are used for electron transporting layers less than 10 nm thick.

Various modifications will be apparent to those skilled in the art. For example, the substrate 10 may be made of plastic (e.g. of polyethylene naphthalate, PEN or polyethylene terephthalate, PET type). The HIL 30 may be preferably 20 to 100 nm thick and more preferably 40 to 60 nm thick. The IL 40 may be preferably 10 to 50 nm thick and more preferably 20 to 30 nm thick. The LEP layer 50 may be preferably 10 to 150 nm thick and more preferably 50 to 70 nm thick.

1. An organic light emitting device comprising
a light emitting layer comprising a light emitting polymer; and
an electron transporting layer deposited on the light emitting layer and comprising an electron transporting material and an n-donor material,
wherein the electron transporting layer comprises at least 20 percent by weight of the n-donor material.

2. The device of claim 1, wherein the electron transporting layer has a thickness of less than 20 nm.

3. The device of claim 1, wherein the electron transporting layer has a thickness of less than 10 nm, preferably less than 5 nm.

4. The device of claim 1, wherein the electron transporting layer comprises at least 40 percent by weight of the n-donor material, or at least 50 percent by weight of the n-donor material.

5. (canceled)

6. The device of claim 1, wherein substantially all molecules of the n-donor material are complexed with molecules of the electron transporting material.

7. An organic light emitting device comprising
a light emitting layer comprising a light emitting polymer; and
an electron transporting layer,
wherein the electron transporting layer comprises an electron transporting material and an n-donor material, at least 20 percent of the molecules of the electron transporting material are complexed with molecules of the n-donor material.

8. The device of claim 7, wherein the thickness of the electron transporting layer is less than 20 nm.

9. The device of claim 7, wherein at least 50 percent of the molecules of the electron transporting material are complexed with molecules of the n-donor material.

10. The device of claim 1, wherein the ratio of molecules of the electron transporting material to molecules of the n-donor material is 1:1.

11. The device of claim 1 wherein the n-donor material is a molecular dopant material, preferably a molecular redox dopant material.

12. The device of claim 1 in which the n-donor material is a transition metal complex, preferably a paddle wheel complex.

13. The device of claim 1 in which the electron transporting layer is in contact with the light emitting layer.

14. The device of claim 1 in which the electron transporting material comprises a phenanthroline compound or a metal quinolate.

15. The device of claim 1, wherein the n-donor material is tetrakis (1,3,4,6,7,8-hexahydro-2H-pyrimido [1,2-a] pyrimidinato) ditungsten (II).

16. The device of claim 1, wherein the electron transporting material has the following formula

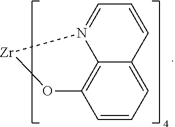

17. The device of claim 1 wherein the electron transporting material has the following formula

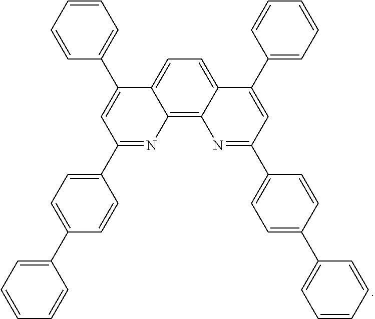 [SMILES: c1ccc(-c2ccc(-c3cc(-c4ccccc4)c4ccc5c(-c6ccccc6)cc(-c6ccc(-c7ccccc7)cc6)nc5c4n3)cc2)cc1]

18. A process for the preparation of an organic light emitting device comprising
depositing a solution of a light emitting polymer over an anode layer; and
depositing an electron transporting material and an n-donor material to form an electron transporting layer over the light emitting polymer,
wherein the electron transporting layer comprises at least 20 percent by weight of an n-donor material.

19. The process according to claim 18, wherein the electron transporting layer has a thickness of less than 20 nm, preferably less than 10 nm.

20. The process according to claim 18, the electron transporting layer comprising at least 40 percent by weight of the n-donor material, or at least 50 percent by weight of the n-donor material.

21. (canceled)

22. The process according to claim 18, wherein depositing the electron transporting material and an n-donor material comprises vapor depositing.
